(19) United States
(12) Patent Application Publication
(10) Pub. No.: US 2022/0285491 A1
(43) Pub. Date: Sep. 8, 2022

(54) TRANSISTOR SOURCE/DRAIN EPITAXY BLOCKER

(71) Applicant: QUALCOMM Incorporated, San Diego, CA (US)

(72) Inventors: Ming-Huei LIN, New Taipei City (TW); Lunwei CHANG, Taichiung (TW); Jun YUAN, San Diego, CA (US)

(21) Appl. No.: 17/189,755

(22) Filed: Mar. 2, 2021

(51) Int. Cl. H01L 29/06; H01L 27/092; H01L 29/423; H01L 29/786; H01L 21/02; H01L 21/8238; H01L 29/66

(52) U.S. Cl. CPC H01L 29/0649; H01L 27/092; H01L 29/0673; H01L 29/42392; H01L 29/78696; H01L 21/02603; H01L 21/02532; H01L 21/823807; H01L 21/823878; H01L 29/66742

(57) ABSTRACT

A transistor cell height may be scaled down without producing undesirable degradation with the use of an isolation structure between adjacent fins of a transistor cell. The transistor cell includes a substrate, a first fin and a second fin located on the substrate, and an isolation structure located on the substrate between the first fin and the second fin.

### FIELD OF DISCLOSURE

This disclosure relates generally to transistor, and more specifically, but not exclusively, to transistor cell heights.

### BACKGROUND

Semiconductor logic chips are prevalent in modern electronics. The logic chips generally incorporate cells that contain a large number of transistors. As the number of transistors increase in a cell, so do the size of the cells and, of course, the overall chip size. To reduce the required increase in chip size to meet the transistor demand, chip designers tend to increase the density of transistors on chip to avoid increasing the overall chip size. To increase the transistor density in advanced nodes (sub-7 nm technology), reduction in standard cell height is the key enabler for area scaling, because contacted poly pitch (CPP) scaling is limited (i.e., due to the saturation of scaling in source/drain contact (CA) minimum width, gate length (Lg), and spacer thickness). Moreover, scaling the spaces between active areas (RX-RX space) and power rails typically saturates at 130 nm. Thus, the industry needs new approaches on reducing RX-RX space to enable sub-150 nm cell height.

Accordingly, there is a need for systems, apparatus, and methods that overcome the deficiencies of conventional approaches including the methods, system and apparatus provided hereby.

### SUMMARY

The following presents a simplified summary relating to one or more aspects associated with the apparatus and methods disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the apparatus and methods disclosed herein in a simplified form to precede the detailed description presented below.

In one aspect, an apparatus transistor may include: a substrate; a first fin located on the substrate; a second fin located on the substrate; and an isolation structure located on the substrate between the first fin and the second fin.

In another aspect, a method for manufacturing a device, may include: providing a substrate; forming a first fin located on the substrate; forming a second fin located on the substrate; and forming an isolation structure located on the substrate between the first fin and the second fin.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates a transistor cell in accordance with some aspects of the disclosure.

FIG. 2 illustrates another transistor cell in accordance with some aspects of the disclosure.

FIGS. 3A-I illustrate a method for manufacturing a transistor cell in accordance with some aspects of the disclosure.

FIGS. 4A-F illustrate another method for manufacturing a transistor cell in accordance with some aspects of the disclosure.

FIG. 5 illustrates a method in accordance with some aspects of the disclosure.

FIG. 6 illustrates a mobile device in accordance with some aspects of the disclosure.

FIG. 7 illustrates various electronic devices that may be integrated with any of the aforementioned devices in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The methods, apparatus, and systems disclosed herein mitigate shortcomings of the conventional methods, apparatus, and systems, as well as other previously unidentified needs. Among the various technical advantages the various aspects disclosed provide, in at least some aspects, the feature of an isolation structure provides for blocker integrated into a transistor to block epitaxial growth. In one aspect, a transistor may include a substrate; a first fin or nano-sheet located on the substrate; a second fin or nano-sheet located on the substrate proximate the first fin or nano-sheet; and an isolation structure located on the substrate between the first fin or nano-sheet and the second fin or nano-sheet. In this aspect, by integrating the isolation structure into the transistor between adjacent or proximate fins or nano-sheets, a blocker region is created between the N region and the P region of respective N type and P type transistors to prevent merger of the N region and P region during epitaxial growth of these regions. In addition, both direct patterning and self-aligned methods for manufacturing such transistors are possible.

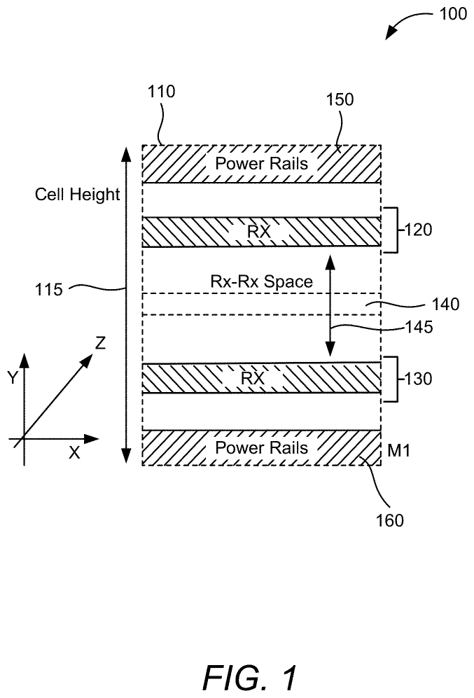

FIG. 1 illustrates a plan view of a transistor cell 100 in accordance with some aspects of the disclosure. As shown in FIG. 1, the transistor cell 100 may include a substrate 110, a first fin 120 located on the substrate 110, a second fin 130 located on the substrate 110 and an isolation structure 140 located on the substrate 110 between the first fin 120 and the second fin 130. In some aspects, the first fin 120 may be part of a first transistor, such as a P type metal oxide semiconductor (PMOS) transistor, and the second fin 130 may be part of a second transistor, such as an N type MOS (NMOS) transistor. However, it will be appreciated that the various aspects disclosed herein are not limited to this configuration and in some aspects, both transistors may be either PMOS or NMOS. In addition, the transistor cell 100 may include a first power rail 150 located on the substrate proximate to the first fin 120 and a second power rail 160 located on the substrate proximate to the second fin 130. In some aspects, the first power rail 150 and second power rail 160 may be formed from a portion of a metal layer (e.g., M1) on the substrate 110.

In some aspects, the isolation structure 140 may be a silicon nitride or similar material. In some aspects, the isolation structure 140 may be similar in shape and size to the first fin 120 and the second fin 130. In addition, a strain may be applied to the isolation structure 140 to boost (or reduce) electron mobility in both the first transistor 120 and the second transistor 130. For instance, where the first transistor 120 is a PMOS transistor and the second transistor 130 is an NMOS transistor, incorporating a Y-direction tensile strain (increasing tensile strain as opposed to decreasing compressive strain) on the transistors may improve the electron mobility in both the N type transistor and the P type transistor. Furthermore, the cut metal gate (CMG) process window during manufacturing may be wider, which reduces the residual gate metal in the trench. The shallower trench produced during the cut metal gate process results in less residual metal being left behind in the trench than would result with a conventional deeper trench. It should also be understood that materials for the isolation structure 140 may be silicon nitride (SiN), silicon oxynitride (SiON), carbon-doped silicon oxynitride (SiON:C), hafnium oxide (HfO₂), lanthanum oxide (La₂O₃), zirconium dioxide (ZrO₂), and similar material such as used for dielectric materials in semiconductor manufacturing. In some aspects, the isolation structure 140 may have: a width of 10 nm to 20 nm fabricated by direct patterning approach, a width of 4 nm to 13 nm fabricated by self-aligned approach, a height of 40 nm to 120 nm, and/or a trench depth of 10 nm to 30 nm. The CMG process for the isolation structure 140 produces a shallower trench than that of typical CMG process without isolation structure 140 (e.g., conventional trench depth ˜60 nm to 100 nm). In the illustrated configuration, the isolation structure 140 allows for a smaller RX-RX space 145 and enables sub-150 nm cell height 115, as discussed in further detail in the following disclosure.

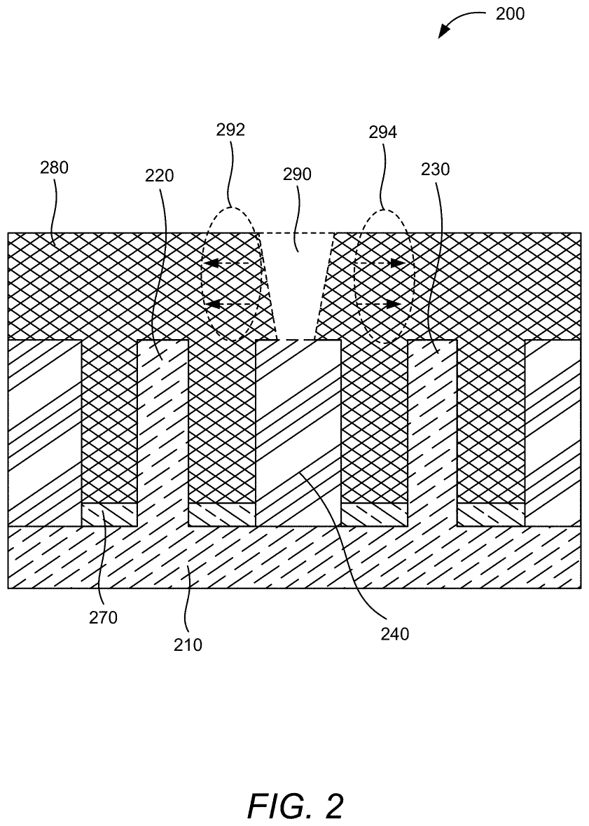

FIG. 2 illustrates a side view of another transistor cell 200 (which may be similar to transistor cell 100) in accordance with some aspects of the disclosure. As shown in FIG. 2, the transistor cell 200 may include a substrate 210, a first fin 220 located on the substrate 210, a second fin 230 located on the substrate 210, and an isolation structure 240 located on the substrate 210 between the first fin 220 and the second fin 230. The isolation structure 240 is configured to block the epitaxial growth during the epitaxially growing of the source/drain active regions over the first fin 220 and the second fin 230. It will be appreciated that as the spacing between the active regions (e.g., RX-RX space 145) is reduced the likelihood the epitaxial growth will merge between the active regions increases. The isolation structure 240 functions as an epitaxy (EPI) blocker preventing the aforementioned merger problem and allowing for reduced spacing (RX-RX space 145) between the active regions.

In some aspects, the first fin 220 may be part of a first transistor, such as a PMOS transistor, and the second fin 230 may be part of a second transistor, such as an NMOS transistor. However, it will be appreciated that the various aspects disclosed herein are not limited to this configuration and in some aspects, both transistors may be either PMOS or NMOS. In addition, the transistor cell 200 may include an insulator layer 270 located on the substrate 210 to cover exposed portions not covered by the other structures located on the substrate 210 and a conductive layer 280 located on the other structures as shown. The insulator layer 270 may be a silicon dioxide (SiO₂) layer (or other insulator) configured to protect the substrate 210 from exposure. The conductive layer 280 may be a metal layer configured for use as a metal in the CMG process, discussed further below.

As shown in FIG. 2, a CMG process may be used to break (separate) the conductive layer 280 (e.g., for forming metal gates) in the transistor cell 200. The CMG process may use oxygen (O) and chlorine (CO, in some aspects, and these CMG etching chemicals (0, CO may change the effective work function (eWF) of the transistors, causing threshold voltage (Vt) changes in the transistors, which can degrade the performance of the transistors. The change in eWF is the result of the chemical diffusion of O and Cl into the conductive layer 280 along edges of a trench 290, formed by the CMG process, in region 292 and region 294. The work function (WF) of a metal can be defined as the minimum energy required to extract one electron from a metal and the effective WF (eWF) is described as the energy necessary for the work function of a metal gate in a transistor.

According to the various aspects disclosed, the trench 290 is shallower and narrower than a conventional trench, in conventional transistor cells. The conventional trench extends all the way through the conductive layer 280 to the insulator layer 270 (or the substrate 210). By having a shallower trench 290, the diffusion regions 292 and 294 are not as extensive as a conventional deeper trench. In the various aspects disclosed, the a deeper trench (such as without EPI blocker) may have a depth of 60 nm-100 nm, a width of 20 nm-30 nm, while a shallower trench (such as with EPI blocker) may have a depth of 1 Onm-50 nm and a width:5 nm-15 nm. Additionally, less residual metal remains in the trench 290 and yield is increased. A smaller gate cut (CT) width enables improved cell height scaling, Further, there is less damage on the conductive layer 280, and the transistor Vt is not negatively impacted.

From the foregoing, it will be appreciated that the use of an isolation structure (e.g., 140 and 240) as an EPI blocker may enable an increase in the transistor density in advanced nodes (sub-7 nm technology for instance), a reduction in standard cell height, avoiding saturation of scaling in source/drain contact (CA) minimum widths and gate lengths (Lg) along with spacer thicknesses. Moreover, in some aspects, without the isolation structure (e.g., 140 and 240) the RX-RX space and power rails may saturate at 130 nm, which limits reducing the RX-RX space to enable sub-150 nm cell height. The isolation structure (e.g., 140 and 240) itself may have a similar shape and size as the fins with a portion proximate the substrate encapsulated by the insulator layer and extending to a similar height and width as the fins above the substrate.

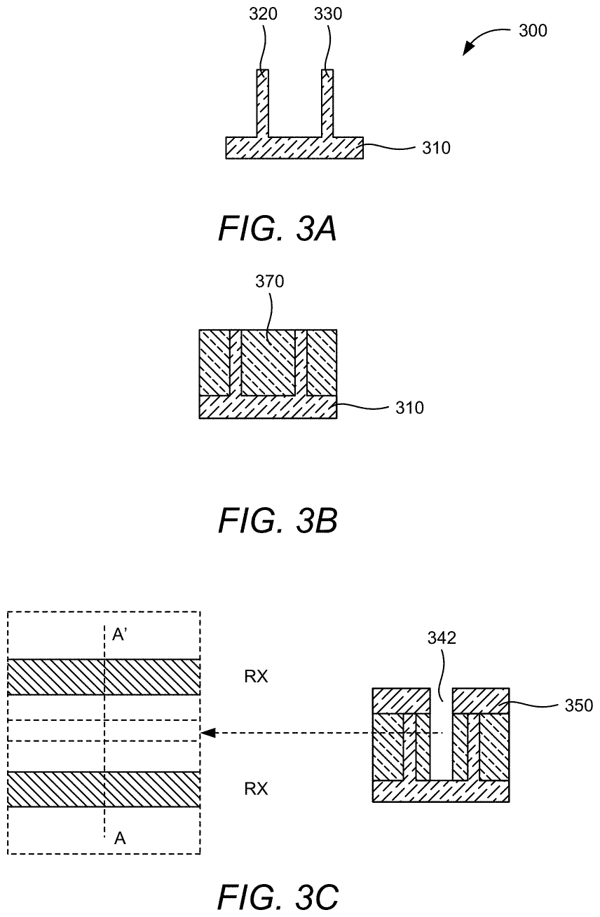

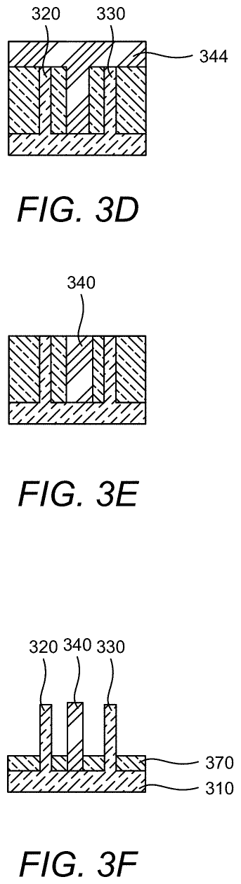

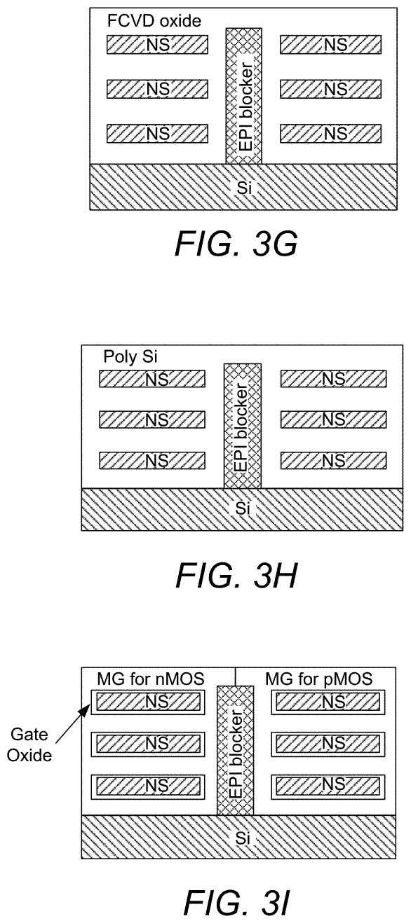

FIGS. 3A-G illustrate a direct patterning method 300 for manufacturing a transistor cell (such as transistor cell 100 and transistor cell 200) in accordance with some aspects of the disclosure. The method 300 may begin as shown in FIG. 3A with providing or forming a substrate 310 along with forming a first fin 320 and a second fin 330 on the substrate 310. In some aspects, the substrate 310 may be a bulk semiconductor substrate formed from conventional semiconductor materials. The substrate 310 may be formed from silicon, germanium or combinations thereof. In some aspects the first fin 320 and the second fin 330 may be formed from the bulk semiconductor substrate. In other aspects, forming the fins may include forming a nano-sheet fin structure as well. The method 300 may continue as shown in FIG. 3B with forming an insulator layer 370 on the substrate 310 (such as a merged deposition). The insulator layer 370 may be formed by a flowable chemical vapor deposition (FCVD) process. The insulator layer 370 may be a silicon dioxide (SiO₂) layer, in some aspects. The method 300 may continue as shown in FIG. 3C with applying a photoresist (PR) film 350 to the insulator layer 370 followed by photo patterning to form a cavity 342.

The method 300 may continue as shown in FIG. 3D with applying a layer of isolation material 344, such as silicon nitride (SiN) after removal of the remaining PR film. The isolation material 344 fills the cavity 342 and covers the top surface of the first fin 320 and the second fin 330. The method 300 may continue as shown in FIG. 3E with forming an isolation structure 340, which in some aspect can be performed by a chemical mechanical polishing process (CMP). The method 300 may continue as shown in FIG. 3F with removing excess portions of the insulator layer 370 to partially expose the first fin 320, the second fin 330, the isolation structure 340, and cover exposed portions of the substrate 310. The remaining portions of manufacturing the transistor cell are not illustrated, but will be understood by those skilled in the art. It will be appreciated that in addition to providing a source/drain EPI blocker function during the formation of the transistors in the front-end-of-line (FEOL) process, the isolation structure 340 also provides a stop portion for the CMG process which results in a shallower trench (e.g., trench 290) produced during the CMG process, as discussed in the foregoing.

FIGS. 3G-I illustrate various nano-sheet structures. The nanosheet structures are generally orientated horizontally and surrounded on all sides by the gate material. It should be understood that the gate-oxide (GOX) may comprise silicon dioxide (SiO₂), hafnium dioxide (HfO₂), hafnium zirconium dioxide (HfZrO₂), zirconium dioxide (ZrO₂), lanthanum (III) oxide (La₂O₃), and hafnium lanthanum oxide (HfLaOₓ). It should also be understood that the metal gate (MG) materials may comprise alloys such as tantalum nitride (TaN), titanium nitride (TiN), titanium aluminum (TiAl), titanium aluminum per nitride (TiAl:N), titanium aluminum per carbon (TiAl:C), titanium nitride per oxide (TiN:O). It should also be understood that the NMOS may comprise an Al concentration higher than that of PMOS by at least 20%. It should also be understood that the NMOS metal gate (MG) may use thinner TiN (or TiN:O) than the PMOS MG and the PMOS MG uses thicker TiN (or TiN:O) than the NMOS MG.

As shown in FIG. 3G, the nano-sheets (NS) and EPI blocker may be encapsulated by a FCVD oxide. As shown in FIG. 3H, the nano-sheets (NS) and EPI blocker may be encapsulated by a poly silicon (Si). As shown in FIG. 3I, the NSs may be surrounded by a gate oxide, the NMOS side may encapsulated the respective NSs with a first material to form a MG for the NMOS and the PMOS side may encapsulated the respective NSs with a second material different from the first material to form a MG for the PMOS.

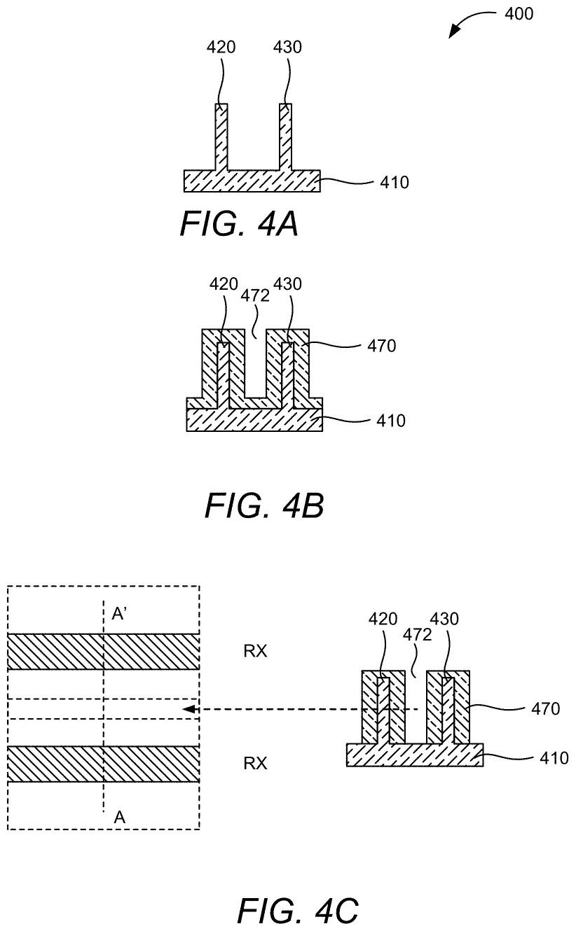

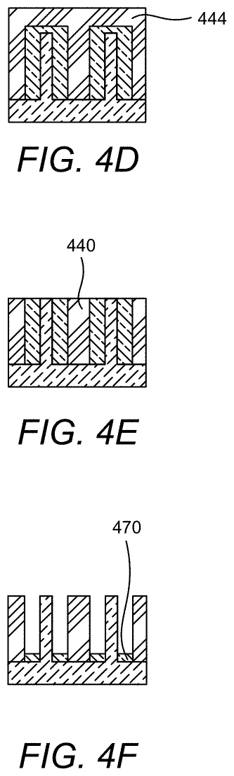

FIGS. 4A-F illustrate a self-aligning method for manufacturing a transistor cell (such as transistor cell 100 and transistor cell 200) in accordance with some aspects of the disclosure. The method 400 may begin as shown in FIG. 4A with providing or forming a substrate 410 along with forming a first fin 420 and a second fin 430 on the substrate 410. In some aspects, the substrate 410 may be a bulk semiconductor substrate formed from conventional semiconductor materials. The substrate 410 may be formed from silicon (Si), germanium (Ge), combinations thereof (SiGe), gallium arsenide (GaAs), and indium phosphate (InP). The transistor channels may comprise Si, Ge, SiGe, GaAs, indium gallium arsenide (InGaAs), indium arsenide (InAs), and gallium nitride (GaN). In some aspects the first fin 420 and the second fin 430 may be formed from the bulk semiconductor substrate. In some other aspects, forming the fins may also include forming a nano-sheet fin structure as well (see, for instance, NS structures in FIGS. 3G-I). The method 400 may continue as shown in FIG. 4B with forming an insulator layer 470 on the substrate 410 (such as a non-merged deposition). As illustrated, the insulator layer 470 is deposited over both the first fin 420 and the second fin 430, but a cavity 472 remains between the first fin 420 and the second fin 430. Forming the insulator layer 470 may be performed by a flowable chemical vapor deposition (FCVD) process, in some aspects. Alternatively, a plasma enhanced CVD (PECVD), a plasma vapor deposition, or thermal oxide may be used in place of a FCVD process to fill the STI with SiO₂. In some aspects, the insulator layer 470 may be a silicon dioxide (SiO₂) layer. The method 400 may continue as shown in FIG. 4C with removing portions of the insulator layer 470. The portions of the insulator layer 470 may be removed by an etching process. The etching process is used to control the cavity opening, which ultimately may be used to control the thickness of the isolation structure (EPI blocker) and is a self-aligned approach. In some aspects, the EPI blocker may have a depth of approximately 40 nm-100 nm and a thickness of approximately 5 nm-20 nm.

The method 400 may continue as shown in FIG. 4D with applying a layer of isolation material 444, which in some aspects may be silicon nitride (SiN). The method 400 may continue as shown in FIG. 4E with forming an isolation structure 440, by removing the excess portions of isolation material 444. In some aspects the excess portions of isolation material 444 may be removed by a chemical mechanical polishing (CMP) process. The method 400 may continue as shown in FIG. 4F with removing excess portions of the insulator layer 470 to expose the first fin 420, the second fin 440 and the isolation structure 440. However, as illustrated, the remaining insulation layer 470 covers portions of the substrate 410 not covered by the first fin 420, the second fin 440, or the isolation structure 440.

It will be appreciated that two fabrication methods have been discussed in the forgoing. A direct patterning approach illustrated in FIGS. 3A-F and a self-aligning approach illustrated in FIGS. 4A-F. In some aspects, the direct pattern approach provides for a simple extreme ultraviolet lithography (EUVL) process, with a minimum width in the range of 10-13 nm due to EUVL line width. The self-aligning approach of FIGS. 4A-F, in some aspects, provides for minimum isolation structure widths that may be adjusted by the thickness of the insulator layer. In some aspects, this allows for sub-10 nm widths, no off-centering issue or the need for any EUVL process.

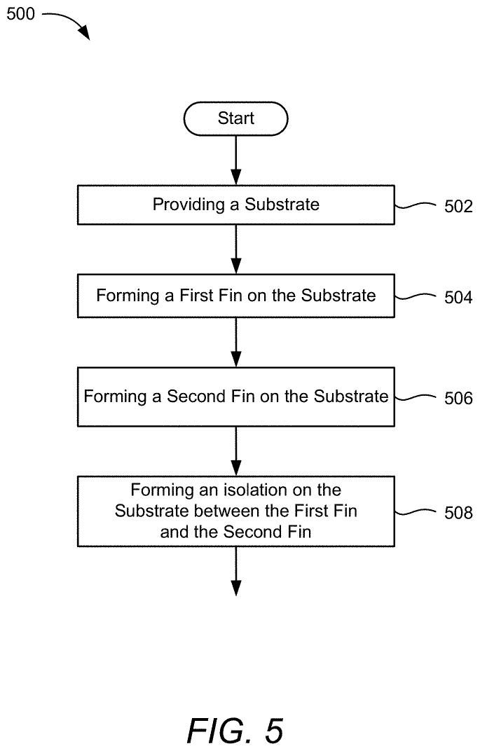

FIG. 5 illustrates a method in accordance with some aspects of the disclosure. As shown in FIG. 5, the method 500 may begin in block 502 with providing a substrate. The method 500 may continue in block 504 with forming a first fin on the substrate. The method 500 may continue in block 506 with forming a second fin on the substrate. The method 500 may conclude in block 508 with forming an isolation structure on the substrate between the first fin and the second fin.

In addition, the method 500 may optionally include one or more of: forming an insulator layer on the substrate in direct contact with the first fin, the second fin, and the isolation structure; wherein the insulator layer comprises a silicon dioxide; wherein the isolation structure comprises a silicon nitride; and separating NMOS transistors from PMOS transistors. It should be understood that the isolation structure serves as an isolator or blocker between NMOS and PMOS transistors in the front-end-of-line (FEOL) process. The power rails and metal layer patterning are formed in back-end-of-line (BEOL) process on top of the FEOL-related isolation structure.

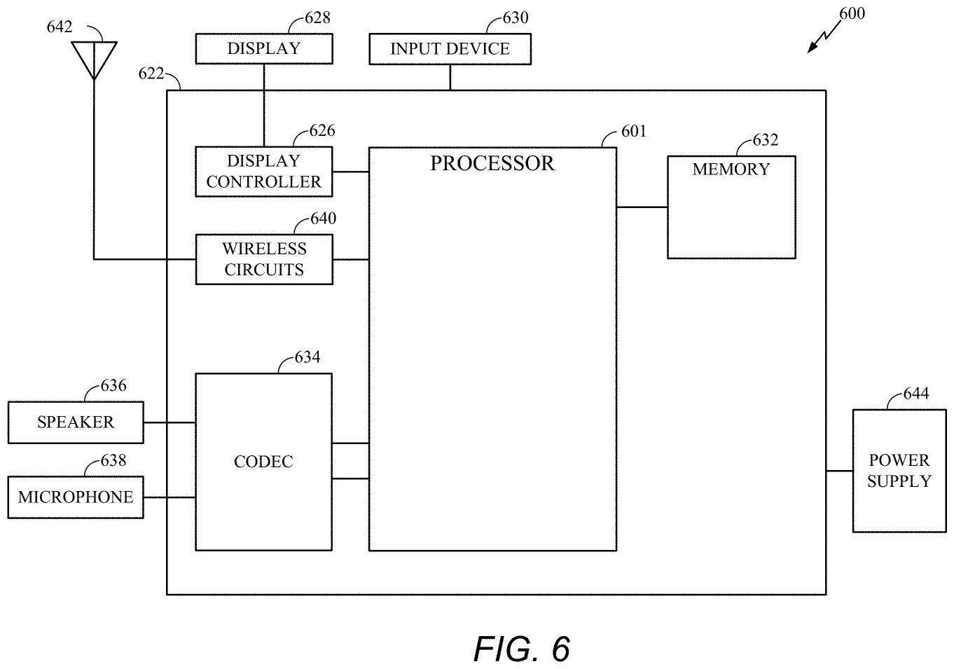

FIG. 6 illustrates an exemplary mobile device in accordance with some examples of the disclosure. Referring now to FIG. 6, a block diagram of a mobile device that is configured according to exemplary aspects is depicted and generally designated mobile device 600. In some aspects, mobile device 600 may be configured as a wireless communication device. As shown, mobile device 600 includes processor 601. Processor 601 may be communicatively coupled to memory 632 over a link, which may be a die-to-die or chip-to-chip link. Mobile device 600 also includes display 628 and display controller 626, with display controller 626 coupled to processor 601 and to display 628.

In some aspects, FIG. 6 may include coder/decoder (CODEC) 634 (e.g., an audio and/or voice CODEC) coupled to processor 601; speaker 636 and microphone 638 coupled to CODEC 634; and wireless circuits 640 (which may include a modem, RF circuitry, filters, etc.) coupled to wireless antenna 642 and to processor 601.

In a particular aspect, where one or more of the above-mentioned blocks are present, processor 601, display controller 626, memory 632, CODEC 634, and wireless circuits 640 can be included in a system-in-package or system-on-chip device 622. Input device 630 (e.g., physical or virtual keyboard), power supply 644 (e.g., battery), display 628, speaker 636, microphone 638, and wireless antenna 642 may be external to system-on-chip device 622 and may be coupled to a component of system-on-chip device 622, such as an interface or a controller.

It will be appreciated that the various components discussed above may include various aspects of the transistor cells including transistors with the isolation structure (e.g., 140, 240, etc.) which may function as an EPI blocker, as disclosed herein. For example, the various aspects may be used in logic circuits in a mobile device 600, such as in the processor 601, memory 632, and other components. However, it will be appreciated that the application of the various aspects disclosed herein are not limited to these examples.

It should be noted that although FIG. 6 depicts a mobile device 600, processor 601 and memory 632 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

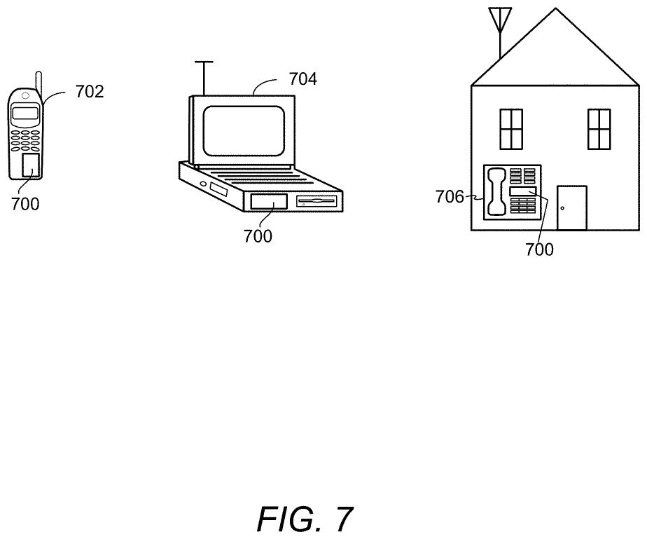

FIG. 7 illustrates various apparatuses and electronic devices that may be integrated with any of the aforementioned integrated device or semiconductor device in accordance with various examples of the disclosure. For example, a mobile phone device 702, a laptop computer device 704, and a fixed location terminal device 706 may each be consider generally user equipment (UE) and may include transistors 700, including isolation structures as described herein. The transistors 700 may be, for example, included in any of the integrated circuits, dies, integrated devices, integrated device packages, integrated circuit (IC) packages, package-on-package devices described herein. The devices 702, 704, 706 illustrated in FIG. 7 are merely exemplary. Other electronic devices may also feature the transistors 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices, functionalities and methods of fabrication may be designed and configured into computer files (e.g., register-transfer level (RTL), Geometric Data Stream (GDS) Gerber, and the like) stored on computer-readable media. Some or all such files may be provided to fabrication handlers who fabricate devices based on such files. Resulting products may include semiconductor wafers that are then cut into semiconductor die and packaged into semiconductor packages, integrated devices, system-on-chip devices and the like, which may then be employed in the various devices described herein.

Accordingly, it will be appreciated that the methods, sequences and/or algorithms described in connection with the various aspects disclosed herein may be incorporated directly in hardware, in a software module executed by a processor, or in a combination of the two. A software module may reside in RAM memory, flash memory, read-only memory (ROM), erasable programmable read-only memory (EPROM), electrically erasable programmable read-only memory (EEPROM), registers, hard disk, a removable disk, a compact disc read-only memory (CD-ROM), or any other form of storage medium known in the art including non-transitory types of memory or storage mediums. A storage medium is coupled to the processor such that the processor can read information from, and write information to, the storage medium. In the alternative, the storage medium may be integral to the processor.

It will be appreciated that various aspects disclosed herein can be described as functional equivalents to the structures, materials and/or devices described and/or recognized by those skilled in the art. It should furthermore be noted that methods, systems, and apparatus disclosed in the description or in the claims can be implemented by a device including means for performing the respective actions of this method. For instance, in one aspect, a transistor (such as transistor cell 100 and transistor cell 200) may comprise: a substrate (such as substrate 110 and substrate 210); a first fin (such as first fin 120 and first fin 220) located on the substrate; a second fin (such as second fin 130 and second fin 230) located on the substrate proximate the first fin; and means for isolation (such as isolation structure 140 and isolation structure 240) located on the substrate between the first fin and the second fin. It will be appreciated that the aforementioned aspects are merely provided as aspects and the various aspects claimed are not limited to the specific references and/or illustrations cited as aspects.

One or more of the components, processes, features, and/or functions illustrated in FIGS. 1-7 may be rearranged and/or combined into a single component, process, feature, or function or incorporated in several components, processes, or functions. Additional elements, components, processes, and/or functions may also be added without departing from the disclosure. It should also be noted that FIGS. 1-7 and its corresponding description in the present disclosure is not limited to dies and/or ICs. In some implementations, FIGS. 1-7 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer. An active side of a device, such as a die, is the part of the device that contains the active components of the device (e.g. transistors, resistors, capacitors, inductors etc.), which perform the operation or function of the device. The backside of a device is the side of the device opposite the active side. As used herein, a metallization structures may include metal layers, vias, pads, or traces with dielectric between, such as a redistribution layer (RDL).

The terminology used herein is for the purpose of describing particular aspects and is not intended to be limiting of aspects of the disclosure. As used herein, the singular forms “a,” “an,” and “the” are intended to include the plural forms as well, unless the context clearly indicates otherwise. It will be further understood that the terms “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can include one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in certain cases. This manner of disclosure should not be understood as an intention that the claimed aspects have more features than are explicitly mentioned in the respective claim. Rather, the disclosure may include fewer than all features of an individual aspect disclosed. Therefore, the following claims should hereby be deemed to be incorporated in the description, where each claim by itself can stand separate. Although each claim by itself can stand separate, it should be noted that—although a dependent claim can refer in the claims to a specific combination with one or a plurality of claims—other aspects can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

For instances, further aspects may include one or more of the following features discussed in the following clauses.

Clause 1. An apparatus comprising: a substrate; a first fin located on the substrate; a second fin located on the substrate; and an isolation structure located on the substrate between the first fin and the second fin.

Clause 2. The apparatus of clause 1, further comprising an insulator layer located on the substrate in direct contact with the first fin, the second fin, and the isolation structure.

Clause 3. The apparatus of clause 2, wherein the insulator layer comprises silicon dioxide (SiO₂).

Clause 4. The apparatus of any of clauses 1 to 3, wherein the isolation structure comprises silicon nitride (SiN), silicon oxynitride (SiON), carbon-doped silicon oxynitride (SiON:C), hafnium oxide (HfO₂), lanthanum oxide (La₂O₃), or zirconium dioxide (ZrO₂).

Clause 5. The apparatus of any of clauses 1 to 4, wherein the isolation structure is disposed in an active region space between an active region of the first fin and an active region of the second fin.

Clause 6. The apparatus of clause 5, wherein the isolation structure is configured to block epitaxial growth on the first fin and epitaxial growth on the second fin in at least a portion of the active region space.

Clause 7. The apparatus of any of clauses 1 to 6, wherein the first fin and the second fin extend substantially perpendicular to the substrate and are formed from a same material as the substrate.

Clause 8. The apparatus of any of clauses 1-7, wherein the substrate comprises at least one of silicon, germanium, or combinations thereof.

Clause 9. The apparatus of any of clauses 1 to 6, and 8, wherein the first fin comprises a first plurality of vertically stacked nanosheets and the second fin comprises a second plurality of vertically stacked nanosheets.

Clause 10. The apparatus of clause 9, wherein each nanosheet comprises at least one of silicon, germanium, or combinations thereof.

Clause 11. The apparatus of any of clauses 1 to 10, wherein the first fin is configured as a P-type metal oxide semiconductor (PMOS) transistor and the second fin is configured as an N-type metal oxide semiconductor (NMOS) transistor.

Clause 12. The apparatus of any of clauses 1 to 11, wherein the apparatus is a transistor cell.

Clause 13. The apparatus of any of clauses 1 to 12, wherein the apparatus is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

Clause 14. A method for manufacturing a device, the method comprising: providing a substrate; forming a first fin located on the substrate; forming a second fin located on the substrate; and forming an isolation structure located on the substrate between the first fin and the second fin.

Clause 15. The method of clause 14, further comprising: forming an insulator layer on the substrate in direct contact with the first fin, the second fin, and the isolation structure.

Clause 16. The method of clause 15, wherein the insulator layer comprises silicon dioxide (SiO₂).

Clause 17. The method of clause 14, further comprising: depositing an insulator material on the substrate, the first fin, and the second fin; forming a cavity between the first fin and the second fin; depositing an isolation material to fill the cavity and form the isolation structure; polishing the device to expose a top surface of the first fin, a top surface of the second fin, and a top surface of the isolation structure; and removing a portion of the insulator material to form an insulator layer and expose the first fin, the second fin, and the isolation structure.

Clause 18. The method of clause 17, further comprising: depositing the insulator material to completely fill between the first fin and the second fin; and performing a photo patterning process on the insulator material to form the cavity.

Clause 19. The method of clause 17, further comprising: controlling a thickness when depositing the insulator material to form a gap between the first fin and the second fin; and etching the insulator material in the gap to form the cavity.

Clause 20. The method of any of clauses 14 to 19, wherein the isolation structure comprises silicon nitride (SiN), silicon oxynitride (SiON), carbon-doped silicon oxynitride (SiON:C), hafnium oxide (HfO₂), lanthanum oxide (La₂O₃), or zirconium dioxide (ZrO₂).

Clause 21. The method of any of clauses 14 to 20, wherein the isolation structure is disposed in an active region space between an active region of the first fin and an active region of the second fin.

Clause 22. The method of clause 21, wherein the isolation structure is configured to block epitaxial growth on the first fin and epitaxial growth on the second fin in at least a portion of the active region space.

Clause 23. The method of any of clauses 14 to 22, wherein the first fin and the second fin extend substantially perpendicular to the substrate and are formed from a same material as the substrate.

Clause 24. The method of any of clauses 14-23, wherein the substrate comprises at least one of silicon, germanium, or combinations thereof.

Clause 25. The method of any of clauses 14 to 22, and 24, wherein the first fin comprises a first plurality of vertically stacked nanosheets and the second fin comprises a second plurality of vertically stacked nanosheets.

Clause 26. The method of clause 25, wherein each nanosheet comprises at least one of silicon, germanium, or combinations thereof.

Clause 27. The method of any of clauses 14 to 26, wherein the first fin is configured as a P-type metal oxide semiconductor (PMOS) transistor and the second fin is configured as an N-type metal oxide semiconductor (NMOS) transistor.

Clause 28. The method of any of clauses 14 to 27, wherein the device is a transistor cell.

Furthermore, in some aspects, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative aspects of the disclosure, it should be noted that various changes and modifications could be made herein without departing from the scope of the disclosure as defined by the appended claims. The functions and/or actions of the method claims in accordance with the disclosure described herein need not be performed in any particular order. Additionally, well-known elements will not be described in detail or may be omitted so as to not obscure the relevant details of the aspects disclosed herein. Furthermore, although elements of the disclosure may be described or claimed in the singular, the plural is contemplated unless limitation to the singular is explicitly stated.

What is claimed is:

1. An apparatus comprising:
a substrate;
a first fin located on the substrate;
a second fin located on the substrate; and
an isolation structure located on the substrate between the first fin and the second fin.

2. The apparatus of claim 1, further comprising an insulator layer located on the substrate in direct contact with the first fin, the second fin, and the isolation structure.

3. The apparatus of claim 2, wherein the insulator layer comprises silicon dioxide (SiO₂).

4. The apparatus of claim 1, wherein the isolation structure comprises silicon nitride (SiN), silicon oxynitride (SiON), carbon-doped silicon oxynitride (SiON:C), hafnium oxide (HfO₂), lanthanum oxide (La₂O₃), or zirconium dioxide (ZrO₂).

5. The apparatus of claim 1, wherein the isolation structure is disposed in an active region space between an active region of the first fin and an active region of the second fin.

6. The apparatus of claim 5, wherein the isolation structure is configured to block epitaxial growth on the first fin and epitaxial growth on the second fin in at least a portion of the active region space.

7. The apparatus of claim 1, wherein the first fin and the second fin extend substantially perpendicular to the substrate and are formed from a same material as the substrate.

8. The apparatus of claim 1, wherein the substrate comprises at least one of silicon, germanium, or combinations thereof.

9. The apparatus of claim 1, wherein the first fin comprises a first plurality of vertically stacked nanosheets and the second fin comprises a second plurality of vertically stacked nanosheets.

10. The apparatus of claim 9, wherein each nanosheet comprises at least one of silicon, germanium, or combinations thereof.

11. The apparatus of claim 1, wherein the first fin is configured as a P-type metal oxide semiconductor (PMOS) transistor and the second fin is configured as an N-type metal oxide semiconductor (NMOS) transistor.

12. The apparatus of claim 1, wherein the apparatus is a transistor cell.

13. The apparatus of claim 1, wherein the apparatus is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

14. A method for manufacturing a device, the method comprising:
providing a substrate;
forming a first fin located on the substrate;
forming a second fin located on the substrate; and
forming an isolation structure located on the substrate between the first fin and the second fin.

15. The method of claim 14, further comprising:
forming an insulator layer on the substrate in direct contact with the first fin, the second fin, and the isolation structure.

16. The method of claim 15, wherein the insulator layer comprises silicon dioxide (SiO₂).

17. The method of claim 14, further comprising:
depositing an insulator material on the substrate, the first fin, and the second fin;
forming a cavity between the first fin and the second fin;
depositing an isolation material to fill the cavity and form the isolation structure;
polishing the device to expose a top surface of the first fin, a top surface of the second fin, and a top surface of the isolation structure; and
removing a portion of the insulator material to form an insulator layer and expose the first fin, the second fin, and the isolation structure.

18. The method of claim 17, further comprising:
depositing the insulator material to completely fill between the first fin and the second fin; and
performing a photo patterning process on the insulator material to form the cavity.

19. The method of claim 17, further comprising:
controlling a thickness when depositing the insulator material to form a gap between the first fin and the second fin; and
etching the insulator material in the gap to form the cavity.

20. The method of claim 14, wherein the isolation structure comprises silicon nitride (SiN), silicon oxynitride (SiON), carbon-doped silicon oxynitride (SiON:C), hafnium oxide (HfO₂), lanthanum oxide (La₂O₃), or zirconium dioxide (ZrO₂).

21. The method of claim 14, wherein the isolation structure is disposed in an active region space between an active region of the first fin and an active region of the second fin.

22. The method of claim 21, wherein the isolation structure is configured to block epitaxial growth on the first fin and epitaxial growth on the second fin in at least a portion of the active region space.

23. The method of claim 14, wherein the first fin and the second fin extend substantially perpendicular to the substrate and are formed from a same material as the substrate.

24. The method of claim 14, wherein the substrate comprises at least one of silicon, germanium, or combinations thereof.

25. The method of claim 14, wherein the first fin comprises a first plurality of vertically stacked nanosheets and the second fin comprises a second plurality of vertically stacked nanosheets.

26. The method of claim 25, wherein each nanosheet comprises at least one of silicon, germanium, or combinations thereof.

27. The method of claim 14, wherein the first fin is configured as a P-type metal oxide semiconductor (PMOS) transistor and the second fin is configured as an N-type metal oxide semiconductor (NMOS) transistor.

28. The method of claim 14, wherein the device is a transistor cell.
